(19) United States
(12) Patent Application Publication
(10) Pub. No.: US 2011/0207301 A1
(43) Pub. Date: Aug. 25, 2011

(54) ATMOSPHERIC PRESSURE CHEMICAL VAPOR DEPOSITION WITH SATURATION CONTROL

(76) Inventors: Kenneth R. Kormanyos, Berkey, OH (US); Nicholas A. Reiter, Gibsonburg, OH (US)

(21) Appl. No.: 12/709,019

(22) Filed: Feb. 19, 2010

(51) Int. Cl. H01L 21/20

(52) U.S. Cl. 438/483; 438/488; 257/E21.133

(57) ABSTRACT

A process for coating a substrate heated to a temperature below the condensation temperature of a semiconductor material at atmospheric pressure is disclosed, the process including the steps of mixing a mass of semiconductor material and a heated inert gas stream, vaporizing the controlled mass of semiconductor material within the inert gas to generate a sub-saturated fluid mixture, directing the sub-saturated fluid mixture at the substrate, wherein the substrate is at substantially atmospheric pressure, depositing a layer of the semiconductor material onto a surface of the substrate, extracting undeposited semiconductor material, and repeating the steps of generating, directing, depositing, and extracting, to minimize an amount of undeposited semiconductor material.

### FIELD OF THE INVENTION

The present invention relates generally to the deposition of a vaporized chemical material on a substrate, and more particularly to a process for depositing a vaporized chemical material and inert gas mixture on a substrate at atmospheric pressure.

### BACKGROUND OF THE INVENTION

Chemical vapor deposition processes such as pyrolytic processes and hydrolytic processes are well known in the art of coating substrates. The physical characteristics of the coating reactants utilized in such processes may be a liquid, a vapor, or a solid dispersed in gaseous mixtures, aerosols, or vaporized or vaporous coating reactants dispersed in gaseous mixtures.

In the process of deposition of a vaporized chemical compound on a glass substrate in the production of photovoltaic devices, the vaporized chemical compound is typically deposited in a vacuum atmosphere as described in U.S. Pat. No. 5,248,349 to Foote, et al.; U.S. Pat. No. 5,945,163 to Powell, et al.; and U.S. Pat. No. 6,676,994 to Birkmire. The systems for carrying out such batch process have typically included a housing having an enclosed deposition chamber that includes a vacuum source for drawing a vacuum within the deposition chamber. The vacuum deposition chamber typically includes heaters for heating the glass sheets as they are passed through the system. The glass sheets pass into the deposition chamber from a vacuum-heating furnace to the vacuum deposition chamber that is maintained at a similar vacuum and temperature setting as the heating furnace.

Powdered cadmium sulfide and powdered cadmium telluride are fed into the vaporization deposition chamber. The films are then deposited onto the heated glass substrates sequentially. The cadmium telluride thin-film material requires a follow-on processing step to enhance the polycrystalline structure of the material so that effective photovoltaic devices can be made from the film stack.

Another method of depositing a vaporized chemical compound on a glass substrate for the production of photovoltaic devices is disclosed in U.S. Pat. No. 7,635,647 for ATMOSPHERIC PRESSURE CHEMICAL VAPOR DEPOSITION to Johnston in which the deposition occurs at atmospheric pressure within a heated inert gas filled furnace as the glass is passed through the furnace. Individually metered masses of semiconductor material, preferably cadmium sulfide (CdS) or cadmium telluride (CdTe) in powdered form, are introduced into a zone which is continuously purged by a stream of inert gas, preferably nitrogen, flowing between an inlet and an outlet at approximately atmospheric pressure. The powder is carried from the inlet, by the inert gas flowing at a controlled rate, into a heated vaporizer consisting of a refractory material. In the vaporizer, the powder is vaporized to form a mixture of the hot inert gas and the vaporized powder material. The outlet of the heated vaporizer is caused to communicate with the interior of a heated zone to cause the vaporized material to impinge upon a surface of the substrate.

In order to control the thin-film deposition rate of the vaporized material and fluid emitted from the apparatus that is applied to the substrate, the mass flow rate of the fluid mixture and the velocity of the substrate are controlled while controlling the temperature of the substrate at a temperature below the condensation point of the vaporized material. As the heated fluid/material mixture impinges onto the cooler substrate, it cools to a temperature below the condensation temperature of the vaporized material. The material condenses from the fluid mixture, in a polycrystalline form, onto the moving substrate as a continuous thin-film layer.

It has been found that thin-film coating systems, based upon the above referred to technologies, are capable of depositing thin films of cadmium sulfide/cadmium telluride photovoltaic material onto commercially available soda-lime glass or low-emissivity (low-E) substrates in a vacuum and at atmospheric pressure. The photovoltaic materials are subsequently treated to re-crystallize the cadmium telluride surface making the film stack ready for further processing into photovoltaic devices.

However, the described deposition processes under a vacuum and at atmosphere each involve a single pass of the material vapor from a vapor generating system over the substrate to obtain the thin-film thereon. The deposition rate of the material on the substrate is dependent upon the rate of vapor molecules impinging the substrate surface. For single pass deposition, the concentration of vapor molecules must be sufficiently high to achieve the required deposition thickness from at least one stream of vapor from the vapor generating system. However, when the vapor concentration of the material becomes higher than the supersaturation level of the vapor at the operating temperature and pressure of the process, loose dust may form due to vapor phase nucleation of the semiconductor material.

Accordingly, it would be desirable to develop a thin-film photovoltaic material deposition process adapted to minimize the vapor phase nucleation of the semiconductor material during the deposition process to minimize dust and particulate formation and to maximize the quality of the thin-film formed on a substrate, thereby minimizing the cost of production thereof.

### SUMMARY OF THE INVENTION

Concordant and congruous with the present invention, a thin-film photovoltaic material deposition process adapted to minimize the vapor phase nucleation of the semiconductor material during the deposition process to maximize the quality of the thin-film formed on a substrate, thereby minimizing the cost of production thereof, has surprisingly been discovered.

It is an object of the present invention to produce a photovoltaic panel by depositing thin-films of semiconductor materials from a mixture of chemical vapors and an inert gas on a substrate at atmospheric pressure. The concentration of the vapor before deposition is controlled to minimize the vapor phase nucleation of the semiconductor material during the deposition process to maximize the quality of the thin-film formed on a substrate and minimize the cost of production thereof. The concentration of the vapor impinging on the substrate is maintained according to the temperature—vapor pressure characteristics of the particular semiconductor species in the particular inert gas at atmospheric pressure.

In one embodiment of the invention, a process for coating a substrate at atmospheric pressure, comprises the steps of vaporizing a controlled mass of semiconductor material at substantially atmospheric pressure within a heated inert gas stream to create a sub-saturated fluid mixture having a temperature above the condensation temperature of the semiconductor material; providing a substrate having a temperature below the condensation temperature of the semiconductor material; providing relative movement between the substrate and a source of the fluid mixture; and directing the fluid mixture at substantially atmospheric pressure onto the substrate, wherein thermal energy transferred from the fluid mixture to the substrate causes the fluid mixture to cool and become substantially fully saturated and depositing a layer of the semiconductor material onto a surface of the substrate while minimizing an amount of undeposited semiconductor material.

### BRIEF DESCRIPTION OF THE DRAWING

The above as well as other objects and advantages of the invention will become readily apparent to those skilled in the art from reading the following detailed description of a preferred embodiment of the invention in the light of the accompanying drawings, in which:

FIG. 1 is a graphical representation of a saturation curve showing the temperature of a fluid mixture including a semiconductor material (CdTe) and an inert gas versus a molar ratio of the semiconductor material and the inert gas at atmospheric pressure; the molar ratio of CdTe to nitrogen indicated is approximately 2×10⁻².

FIG. 2 is another graphical representation of a saturation curve showing the temperature of a fluid mixture including a semiconductor material (CdTe) and an inert gas versus a molar ratio of the semiconductor material and the inert gas at atmospheric pressure; the molar ratio of CdTe to nitrogen indicated is approximately 4×10⁻⁴, and

FIG. 3 is another graphical representation of a saturation curve showing the temperature of a fluid mixture including a semiconductor material (CdTe) and an inert gas versus a molar ratio of the semiconductor material and the inert gas at atmospheric pressure, the molar ratio of CdTe to nitrogen indicated is approximately 2×10⁻³.

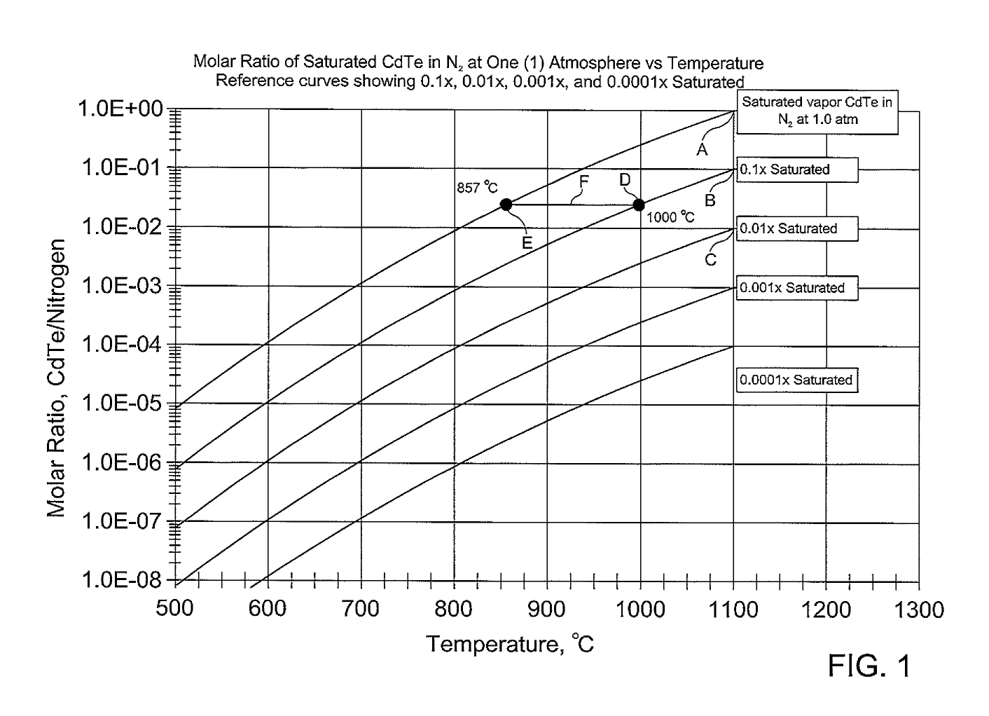

Each of FIGS. 1-3 show the same saturation curves but with different molar ratios of the semiconductor material and the inert gas at atmospheric pressure illustrated as examples.

### DETAILED DESCRIPTION OF THE PREFERRED EMBODIMENT

Individually metered masses of semiconductor material, preferably cadmium sulfide (CdS) or cadmium telluride (CdTe) in powdered form, are introduced into a zone which is continuously purged by a stream of inert gas, preferably nitrogen, flowing between an inlet and an outlet at approximately atmospheric pressure. The powder is carried from the inlet, by the inert gas flowing at a controlled rate, into a heated vessel in which the powder is sublimated. The heated vessel is designed so that a fluid may be passed therethrough, and heated to a desired and controlled temperature as it passes therethrough. The desired temperature is a temperature at which the semiconductor material will vaporize. The heated vessel may be a heated packed bed, as desired. The powdered semiconductor material is sublimated in the inert gas in a heated packed bed as it passes through the interstitial voids between the media of the packed bed. The outlet of the heated vessel is caused to flow into the interior of a heated zone to distribute the inert gas and sublimated material mixture (hereinafter “the fluid mixture”) to the substrate.

Individually metered masses of semiconductor material, preferably cadmium sulfide (CdS) or cadmium telluride (CdTe) in powdered form, may be introduced into the heated vessel. The heated vessel is continuously purged by a stream of inert gas carrying the powder material so that the semiconductor material vaporizes at substantially the same rate that the semiconductor material is introduced therein and the mixture is heated. Metering in a known mass of semiconductor at a known mass flow rate into the heated vessel on a “just in time” basis provides for additional process control and facilitates process cost optimization. The powder is carried from the inlet, by the inert gas flowing at a controlled rate, into the heated vessel. The interior of the heated vessel contains a set of low pressure drop, fixed fluid mixing vanes, in which the powder sublimes into a vapor as it passes therethrough, thereby mixing the heated inert gas and the semiconductor material vapor. Alternately, the interior of the heated chamber could comprise a heated packed bed of refractory material media in which the powder sublimes into a vapor as it passes through the interstitial voids between the media of the packed bed. The outlet of the heated vessel is in fluid communication with the heated zone to facilitate distribution of the vaporized material fluid stream to the substrate.

Alternative powder sublimation and vaporization methods through which the metered powder mass and carrier inert gas are heated may be employed for generating the fluid mixture. The alternative methods may include, but are not necessarily limited to, heated fluidized beds in which the inert carrier gas is heated and the powder is vaporized; thermal “flash” vaporizers that heat the inert carrier gas and vaporize the powder; and atmospheric pressure thermal spray units that heat the inert carrier gas and vaporize the powder.

By controlling the feed rate of the semiconductor material and the flow rate of the inert carrier gas, a molar ratio of semiconductor to inert gas is determined. Once the molar ratio is known, and knowing the desired temperature of the heated vessel and fluid mixture, the temperature-molar ratio curves shown in FIG. 1 can be used to determine the saturation of the fluid mixture. To use the methods described herein, a sub-saturated fluid mixture is desired. FIG. 1 shows the temperature-molar ratio and saturation curves for CdTe and nitrogen (N₂). It is understood that curves similar to the curves illustrated in FIG. 1 and described herein may be obtained for the other semiconductor materials described herein, such as CdS, for example. The heated sub-saturated fluid mixture is then directed into an apparatus for producing a desired directed flow of the fluid toward the surface of a substrate at substantially atmospheric pressure. The substrate is typically a soda-lime glass, preferably having a low-E coating that is transparent and electrically conductive. An example of such glass is produced by Pilkington Glass Co. and is designated as TEC-15. The surface of the substrate is maintained at a temperature of from about 400° C. to about 600° C.

The apparatus for producing the desired directed flow of the fluid mixture comprises a series of individual passageways adapted to cause a series of direction and velocity changes in the transient fluid as the fluid flows through the passageways. The apparatus is maintained above the sublimation temperature of the semiconductor, to prevent condensation of the material within the passageways. Such fluid flow apparatus evenly distributes the fluid mixture to an elongate outlet nozzle of a vapor deposition and extraction head, and enables uniform flow at constant mass flow distribution to the surface of the substrate. The above action causes the molecules of the fluid mixture to be evenly distributed throughout the length of the elongate outlet nozzle, and causes the molecules to travel from the outlet nozzle in a generally parallel path and at a uniform velocity, producing a flow of constant velocity and mass distribution directed toward the substrate. The velocity of the fluid mixture exiting the outlet nozzle may be regulated by controlling the mass flow rate at which the fluid mixture is introduced at the inlet.

To facilitate a continuous deposition process, relative movement between the substrate and the nozzle is provided. It is understood that the orientation of the substrate and the outlet nozzle may vary so long as the flow of the fluid mixture exiting the outlet nozzle contacts the substrate. The substrate may be horizontally disposed and transported on a cushion of air or on a conventional mechanical conveyor system, as known in the art. Alternatively, the substrate may be vertically disposed and transported via a tong and track system, or the substrate may be transported on a track or other support system with the substrate held substantially vertically, or at a desired angle greater than forty-five degrees (45°), by a cushion of inert gas. If the substrate is transported on a track or other support system and held vertically or at the desired angle by a cushion of inert gas, the cushion of inert gas may be directed at a side of substrate opposite from the side on which semiconductor materials are deposited. Alternatively, the cushion of inert gas may be directed at the same side of the substrate on which the semiconductor materials are deposited.

In order to control the thin-film deposition rate of the vaporized material within the fluid emitted from the apparatus being applied to the substrate, the mass flow rate of the fluid mixture, the velocity of the substrate, the saturation of the fluid mixture, and the temperature of the fluid mixture are controlled. The fluid mixture is sub-saturated with the sublimated semiconductor, and is preferably at or below 0.10× saturated. The substrate is maintained at a temperature below the condensation point of the sublimated semiconductor material. The temperature of the substrate is also maintained at a desired temperature so that, when contacted by the sub-saturated fluid mixture, thermal energy will transfer from the fluid mixture to the substrate and the sub-saturated fluid mixture will become substantially fully saturated. For example, if the sub-saturated fluid is at about 1000° C. and 0.1× sub-saturation, that is, the sub-saturated fluid is at point D on curve B of FIG. 1, and the sub-saturated fluid mixture is impinged upon a substrate below 857° C., the fluid mixture will cool to approximately 857° C. and become fully saturated at point E on curve A. The transition of the fluid mixture from sub-saturated to saturated due to the cooling of the fluid mixture that occurs at impingement on the substrate is graphically illustrated by line F on FIG. 1.

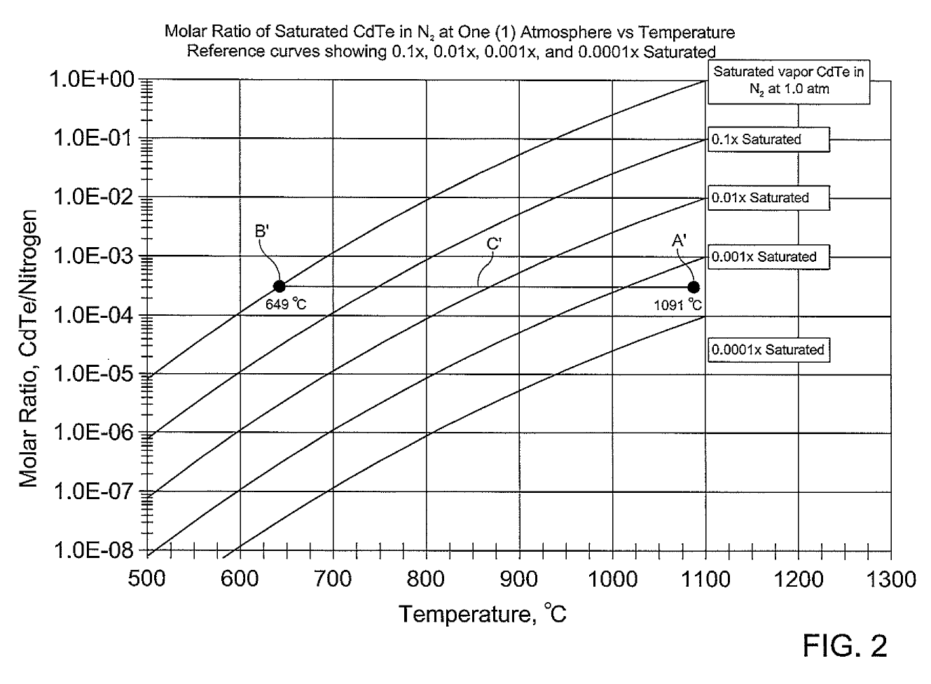

In another example, CdTe semiconductor material is fed at 1.65 grams/minute into a nitrogen gas stream flowing at 400 standard liters per minute. The solid-gas two-phase mixture is heated to about 1091° C. causing vaporization of the CdTe material to form a heated vapor phase mixture. The saturated molar ratio for CdTe in nitrogen at about 1091° C. is approximately 1:1 for a fully saturated mixture. The controlled feed rate of CdTe results in a mixture molar ratio of 0.0004 moles CdTe/mole nitrogen at about 1091° C. As shown in FIG. 2, the fluid mixture under these conditions is at a sub-saturation of 0.0004× the saturated level, shown at a point A′. The fluid mixture is impinged upon a glass substrate having a temperature between about 530° C. and about 550° C. The mixture undergoes cooling as its flow is modified for application to the width of the glass plate. The mixture exits the distribution nozzle at approximately 850° C. at which point it is still sub-saturated to militate against vapor phase nucleation. The heated impinging fluid mixture saturates during the cooling caused by impingement on the cooler substrate, thereby causing the deposition of the semiconductor materials in the fluid mixture on the glass substrate with minimized undeposited semiconductor material (CdTe). The fluid mixture will cool to a temperature of about 649° C., as shown at a point B′, and be substantially fully saturated. The transition of the fluid mixture from sub-saturated to saturated due to the cooling of the fluid mixture that occurs at impingement on the substrate is graphically illustrated by line C′ on FIG. 2.

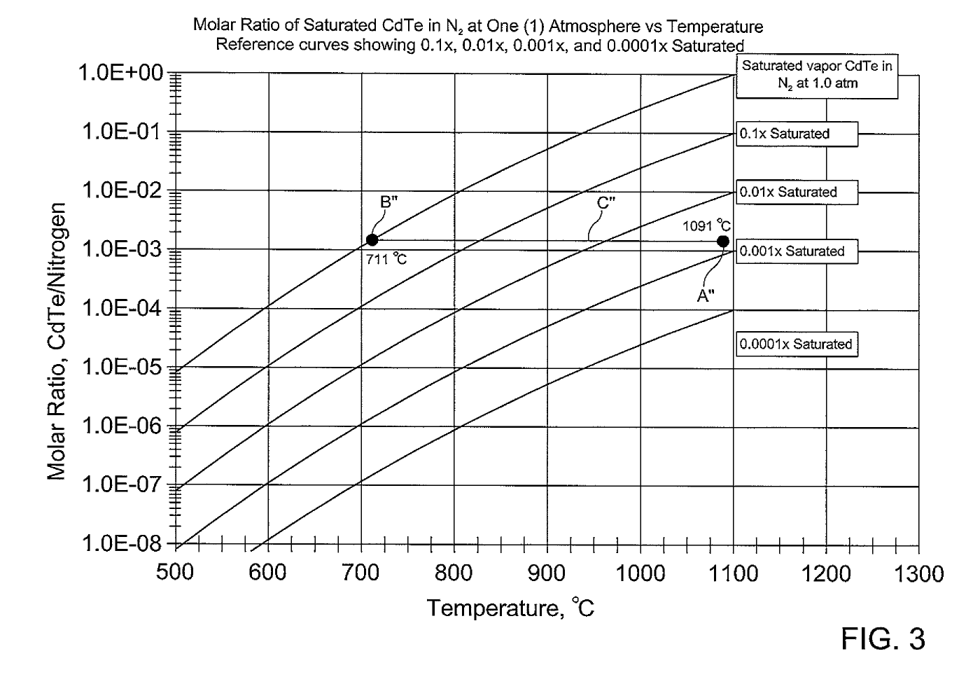

In a third example, CdTe semiconductor material is fed at 6.5 grams/minute into a nitrogen gas stream flowing at 400 standard liters per minute. The solid-gas two-phase mixture is heated to about 1091° C. causing vaporization of the CdTe material and forming a heated vapor phase mixture. The saturated molar ratio for CdTe in nitrogen at about 1091° C. is approximately 1:1 for a fully saturated mixture. The controlled feed rate of CdTe results in a mixture molar ratio of 0.0015 moles CdTe/mole nitrogen at about 1091° C. As shown in FIG. 3, the fluid mixture under these conditions is at a sub-saturation of 0.002× the saturated level shown at a point A″. The fluid mixture is impinged upon a glass substrate having a temperature between about 530° C. and about 550° C. The mixture undergoes some cooling as its flow is modified for application to the width of the glass plate. The mixture exits the distribution nozzle at about 850° C. at which point it is still sub-saturated to militate against vapor phase nucleation. The heated fluid mixture saturates during the cooling caused by impingement on the cooler substrate, thereby causing the deposition of the semiconductor materials in the fluid mixture on the glass substrate with minimized undeposited semiconductor material (CdTe). The fluid mixture will cool to a temperature of about 711° C., as shown at a point B″, and be substantially fully saturated. The transition of the fluid mixture from sub-saturated to saturated due to the cooling of the fluid mixture that occurs at impingement on the substrate is graphically illustrated by line C″ on FIG. 3.

It has been determined that concentrations of semiconductor material in an inert gas may be successfully deposited on substrates using the process described herein using sub-saturated fluid mixtures having relative saturations of 0.0001× to 0.90× fully saturated. More specifically, favorable results have been obtained with sub-saturated fluid mixtures having relative saturations of 0.001× to 0.10× fully saturated. Deposition rates of up to approximately 2 μm/second have been demonstrated using the process described herein.

At the same time the fluid mixture cools to a temperature below the condensation temperature of the sublimated material, the sub-saturated fluid mixture becomes fully saturated during impingement on the substrate. Because the substrate is maintained at a temperature below the condensation temperature of the semiconductor material and because the fluid mixture is fully saturated and not super-saturated upon contact with the substrate, the semiconductor material condenses from the fluid mixture, in a polycrystalline form, onto the moving substrate as a continuous thin-film layer and condensed material that does not form a thin-film layer on the substrate that forms dust or other particulate matter is minimized. To militate against contamination of the substrate having a thin-film layer, any condensed material dust and particulates, along with the inert gas from the fluid mixture, are extracted by an extraction system.

While there may be a number of different systems for evenly distributing the semiconductor material vapor and inert gas mixture on the surface of the transient glass substrate, it is contemplated that the apparatus illustrated and described in U.S. Pat. No. 4,200,446 to Koontz or U.S. Pat. No. 4,509,526 to Hofer et al. may provide satisfactory results. Other methods include arrays of discrete holes or discrete slots serving as an exit nozzle of a deposition device are known to those skilled in the art.

The deposition of any number of consecutive layers of cadmium sulfide and/or cadmium telluride by the method and apparatus described above, to prepare a laminar structure, is contemplated by the present invention.

Subsequent to the deposition of a cadmium telluride polycrystalline thin-film, a re-crystallization step would be required to allow the production of photovoltaic devices from the laminar thin-film stack. It has been found that this step can be achieved in less than one minute by subjecting the hot cadmium telluride film to a hot gaseous atmosphere of dilute hydrogen chloride in nitrogen at substantially one atmosphere of pressure. However, it is understood that this step may be achieved in any time frame based on varying process conditions and other process design considerations. The ability to control the re-crystallization of the cadmium telluride while maintaining the temperature of the substrate eliminates cool-down and re-heating of the substrate/film-stack assembly during the re-crystallization step. The use of a “dry” re-crystallization step eliminates the use of a toxic cadmium chloride solution and its application apparatus. Typically, a glass substrate exiting the in-line re-crystallization process would have a temperature from about 620° C. to about 630° C. This temperature range allows the glass to be thermally tempered by cool quenching gas flows as the substrate/film-stack exits the processing line.

The above-described process relates to a method for producing a thin-film cadmium sulfide/cadmium telluride photovoltaic material on the surface of a soda-lime glass substrate, to provide large area photovoltaic panels. However, it must be understood that the concept of atmospheric vapor deposition can be extended to include other thin-film materials that are normally deposited in a vacuum.

Thin-film photovoltaic materials that could be considered are CIGS (copper-indium-gallium-diselenide), CdS/CIS-alloy (cadmium sulfide/copper-indium-selenium alloy), amorphous silicon or thin-film polycrystalline silicon, and Zn (O, S, OH)ₓ/CIGS (zinc oxide sulfide hydroxide/copper-indium-gallium-diselenide).

Other thin-film materials that can be considered for application to glass substrates are optical coatings such as multi-layer stacks used for very low emissivity films and anti-reflection films. Other value added features such as improved durability films, self-cleaning films, photo-optic, and electro-optic films could be developed using the inventive atmospheric pressure deposition concept.

The process of atmospheric pressure deposition of thin-film materials could be applied to a variety of substrate materials for enhancement of their surface properties. Substrates that could be considered include polymeric materials, ceramics, metals, wood, and others.

What is claimed is:

1. A process for coating a substrate heated to a temperature below the condensation temperature of a semiconductor material at atmospheric pressure, comprising the steps of:
mixing a mass of semiconductor material and a heated inert gas stream;
vaporizing the controlled mass of semiconductor material within the inert gas to generate a sub-saturated fluid mixture;
directing the sub-saturated fluid mixture at the substrate, wherein the substrate is at substantially atmospheric pressure;
depositing a layer of the semiconductor material onto a surface of the substrate;
extracting undeposited semiconductor material;
repeating the steps of generating, directing, depositing, and extracting, to minimize an amount of undeposited semiconductor material.

2. The process of claim 1, wherein thermal energy transferred from the sub-saturated fluid mixture to the substrate causes the fluid mixture to cool and become substantially fully saturated thereby depositing a layer of the semiconductor material onto a surface of the substrate while minimizing an amount of undeposited semiconductor material.

3. The process according to claim 1, wherein the semiconductor material is one of cadmium sulfide and cadmium telluride.

4. The process according to claim 1, wherein the inert gas is nitrogen.

5. The process according to claim 1, wherein the temperature of the fluid mixture ranges from about 500 degrees C. to about 1100 degrees C.

6. The process according to claim 1, wherein the substrate comprises glass.

7. The process according to claim 6, wherein the glass includes a transparent, electrically conductive coating.

8. The process according to claim 1, wherein the substrate has a temperature ranging from about 400 degrees C. to about 600 degrees C.

9. The process according to claim 1, wherein the steps of vaporizing, directing, and depositing are repeated at least once, to deposit at least one additional layer of semiconductor material on the substrate.

10. The process according to claim 1, wherein a metered mass of semiconductor material is mixed with the heated inert gas to form the fluid mixture.

11. The process according to claim 1, providing a bulk quantity of semiconductor material for mixing with the heated inert gas to form the fluid mixture.

12. The process according to claim 1, wherein the bulk quantity of semiconductor material is provided in a heated packed bed of refractory material media.

13. The process according to claim 1, further comprising a step of maintaining a desired molar ratio of semiconductor material and inert gas in the fluid mixture to minimize an amount of undeposited semiconductor material.

14. The process according to claim 1, wherein the sub-saturated fluid mixture has a relative saturation of between about 0.0001× and about 0.90× full saturation.

15. The process according to claim 14, wherein the sub-saturated fluid mixture has a relative saturation of between about 0.001× and about 0.10× full saturation.

16. The process according to claim 1, wherein the rate of depositing the layer of semiconductor material on the heated substrate is up to about 2 μm/second.

17. A process for coating a substrate heated to a temperature below the condensation temperature of a semiconductor material at atmospheric pressure, comprising the steps of:
mixing a mass of semiconductor material and a heated inert gas stream;
vaporizing the controlled mass of semiconductor material within the inert gas to generate a sub-saturated fluid mixture;
directing the sub-saturated fluid mixture at the substrate, wherein the substrate is at substantially atmospheric pressure;
depositing a layer of the semiconductor material onto a surface of the substrate, wherein thermal energy transferred from the sub-saturated fluid mixture to the substrate causes the fluid mixture to cool and become substantially fully saturated thereby depositing a layer of the semiconductor material onto a surface of the substrate while minimizing an amount of undeposited semiconductor material.;
extracting undeposited semiconductor material;
repeating the steps of generating, directing, depositing, and extracting, to minimize an amount of undeposited semiconductor material.

18. The process according to claim 17, wherein the sub-saturated fluid mixture has a relative saturation of between about 0.0001× and about 0.90× full saturation.

19. The process according to claim 18, wherein the sub-saturated fluid mixture has a relative saturation of between about 0.001× and about 0.10× full saturation.

20. A process for coating a substrate heated to a temperature below the condensation temperature of a semiconductor material at atmospheric pressure, comprising the steps of:
mixing a mass of semiconductor material and a heated inert gas stream;
vaporizing the controlled mass of semiconductor material within the inert gas to generate a sub-saturated fluid mixture;
directing the sub-saturated fluid mixture at the substrate, wherein the substrate is at substantially atmospheric pressure and the sub-saturated fluid mixture has a relative saturation of between about 0.0001× and about 0.90× full saturation;
depositing a layer of the semiconductor material onto a surface of the substrate;
extracting undeposited semiconductor material;
repeating the steps of generating, directing, depositing, and extracting, to minimize an amount of undeposited semiconductor material.
